(19) United States
(12) Patent Application Publication
(10) Pub. No.: US 2009/0120669 A1
(43) Pub. Date: May 14, 2009

(54) MICRO DEVICE WITH MICROTUBES

(75) Inventor: Romano Hoofman, Geel (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/296,703

(22) PCT Filed: Apr. 3, 2007
(86) PCT No.: PCT/IB2007/051179

§ 371 Date: Oct. 10, 2008

(30) Foreign Application Priority Data
Apr. 13, 2006 (EP) 06112632.2

(51) Int. Cl. H05K 1/00; B05D 3/00

(52) U.S. Cl. 174/252; 427/331

(57) ABSTRACT

The current invention is related to a micro device with microtubes that can be used as a heat exchanger for ultra fast cooling or heating of liquids. Using a damascene metal level in combination with thermal degradable polymer (TDP) enables the manufacturing of compact system of microtubes only separated by a monolayer of metallic barrier material. Due to the small distance (i.e. the thickness of the barrier) between two separate microtubes a highly efficient heat transfer between two fluids circulating in the microtubes is enabled.

The current invention is related to a micro device with microtubes that can be used as a heat exchanger for ultra fast cooling or heating of liquids.

In U.S. Pat. No. 6,031,286 a semiconductor device and a method to manufacture such a device with single or multi layers of buried micro pipes are described. A buried micro pipe is formed by filling a trench that has a height which is larger than a width thereof, so that the trench filler material lines sidewalls and bottom of the trench, and covers the top of the trench to form the micro pipe within the trench. Another layer can be formed over the filler material and planarized. Alternatively, the filler material itself can be planarized. Forming trenches in the planarized layer, and repeating the above steps forms a second set of buried micro pipes in these new trenches. This forms a semiconductor device having multiple layers of buried micro pipes. Via holes may be etched to contact a micro pipe, or to interconnect micro pipes buried at different levels. Thus, instead of eliminating defective voids in trenches, the voids are controlled to form the micro pipes, which may be used to circulate a cooling fluid, or lined with a conductive material to form a micro light pipe channel, or buried conductive pipes. The disadvantage of this devices and the method is that the distance between the different micro pipes is large causing an inefficient cooling. Lengthy systems of micro pipes are needed limiting the velocity of cooling and wasting substrate area.

It is an objective of the present invention to provide a method for manufacturing highly efficient and compact heating or cooling devices. The objective is achieved by means of a method for manufacturing a micro device comprising the steps of:
providing a substrate;
providing a first disposable layer;
providing at least one barrier layer;
providing a second disposable layer;
building a first microtube by removing the first disposable layer and
building a second microtube by selectively removing the second disposable layer.

The substrate can be any kind of substrate made of glass, ceramic or silicon. Further the substrate can comprise additional layers of at least one material. Using two different disposable layers enables the production of microtubes essentially arranged in one plane essentially parallel to the substrate by structuring the disposable layers by means of standard semiconductor methods as e.g. optical lithography and wet etching. Only one barrier layer separates two adjacent microtubes taking a cross section perpendicular to the extension of the microtubes. The barrier layer can be around 10 nm. The small distance between two separate microtubes enables highly efficient heating or cooling of liquids if two liquids of different temperatures flow through the microtubes especially if the barrier layer does have a high thermal conductivity. The microtubes can also be connected to each other at one or more points depending on the application.

In one embodiment of the invention the method for manufacturing a micro device comprises the additional steps of:
providing a permeable layer;
removing the first disposable layer via the permeable layer;
providing and patterning an encapsulation layer and
selectively removing the second disposable layer embedded in the at least one barrier layer.

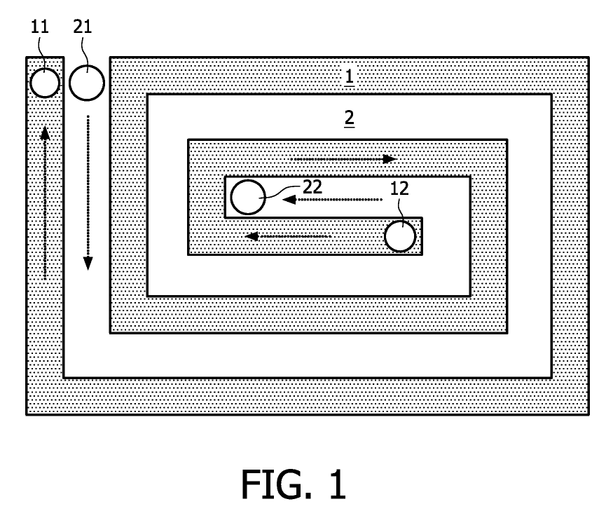

The first disposable layer can be a thermal degradable polymer (TDP) that can be removed by means of heat through the permeable layer as described e.g. in EP 1577939 A2 (see e.g. FIG. 1-FIG. 12 and the belonging description, especially paragraphs 10 and 11). The TDP decomposes during the heating procedure and evaporates through the permeable layer leaving one or more microtubes underneath the permeable layer depending on the structuring of the first disposable layer. Another example of the first disposable layer could be an oxide layer, which can be selectively removed by HF-exposure through a porous organic layer on top. The second disposable layer can be metal as copper embedded in one or more barrier layers. The metal can be removed through openings in the encapsulation layer and the barrier layer by means of an etching solution etching the metal very fast but etching the barrier layer (Ti, TiN, Ta, TaN, WN) very slow. Preferably each microtube does have two openings where the etching solution can enter the microtube etching the metal embedded in the barrier layer or layer step by step until all metal in the microtube formed by the barrier layers is etched. The thickness of the barrier layer depends on the relation between the cross-sectional area perpendicular to the extension of the microtube and the length of the microtube on the one side and the selectivity of the etching solution with respect to the second disposable layer and the barrier layer on the other side. The encapsulation layer can comprise SiN or TEOS.

In a further embodiment the method for manufacturing a micro device comprises the steps of:
depositing a first disposable layer on a substrate;
structuring the first disposable layer;
depositing a first barrier layer on top of the structured first disposable layer;
depositing a second disposable layer on top of the first barrier layer;
removing the second disposable layer and the first barrier layer up to the structured first disposable layer;
plating the residual structures of the second disposable layer with a second barrier layer;
depositing a permeable dielectric layer on top of the second barrier layer and the structured first disposable layer;
removing the first disposable layer through the permeable dielectric layer;
depositing an encapsulation layer on top of the permeable dielectric layer;
opening the second disposable layer through the encapsulation layer, the permeable dielectric layer and the second barrier layer building at least two vias to the second disposable layer;
depositing a third barrier layer;
removing the third barrier layer on top of the second disposable layer in building at least two openings and
selectively removing the second disposable layer.

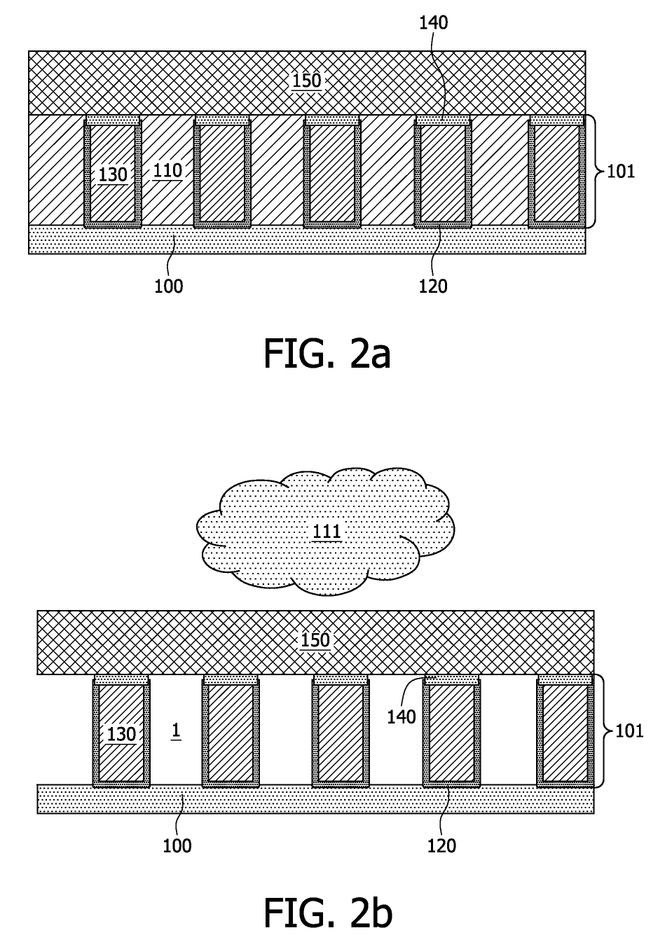

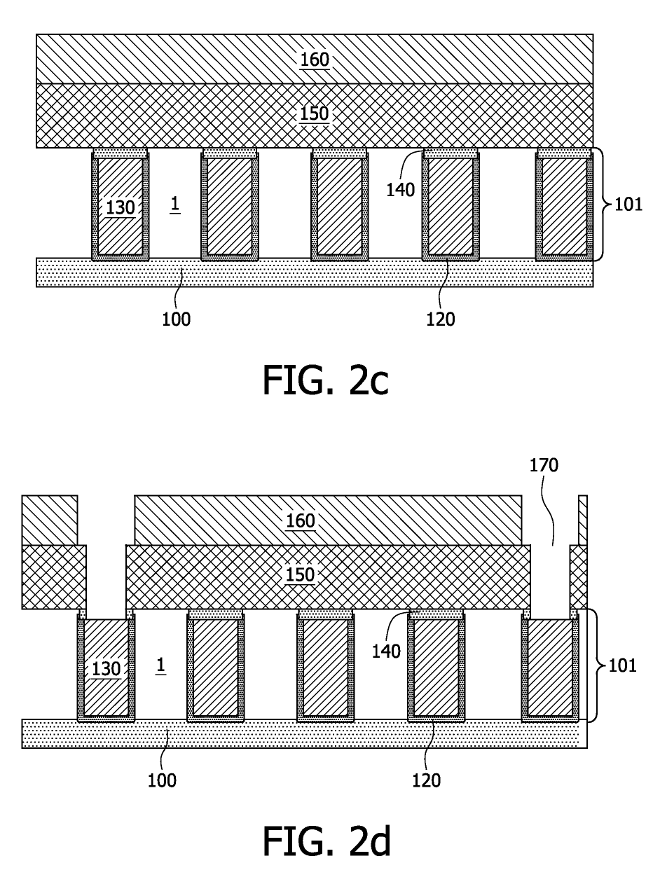

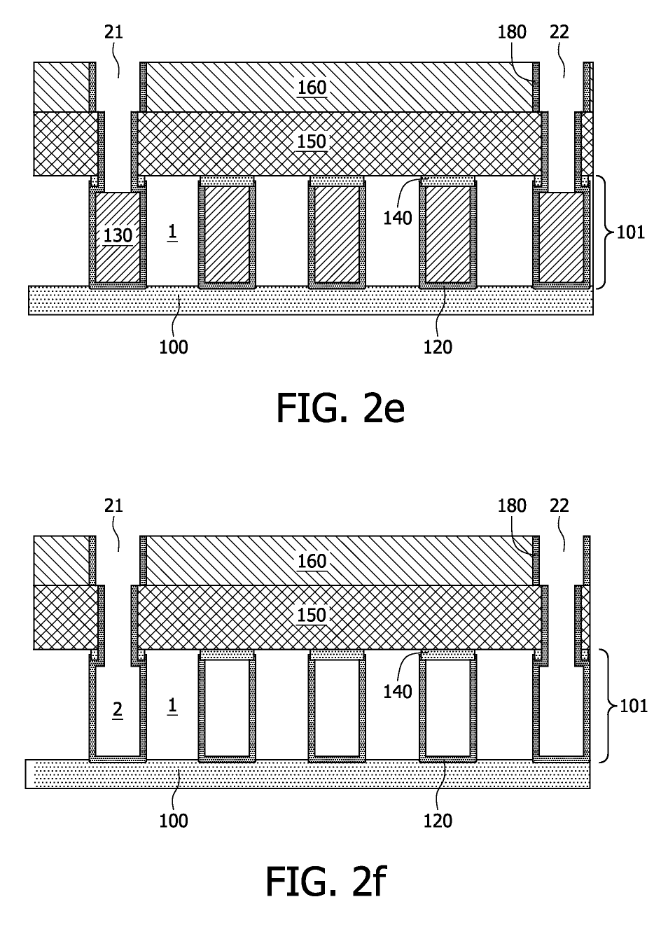

The first disposable layer can be a thermal degradable polymer (TDP) that can be removed by means of heat through the permeable layer as described e.g. in EP 1577939 A2 (see e.g. FIG. 1-FIG. 12 and the belonging description, especially paragraphs 10 and 11). The second disposable layer can be metal that can be removed by means of an etching solution etching the metal very fast but etching the barrier layer very slow. The metal layer and the barrier layer on top of the TDP can be removed by planarization techniques as described e.g. in WO 2004/023550 A1 (see e.g. FIG. 1 and FIG. 2 and the belonging description). The second barrier layer is used to enclose the residues of the metal. It can be deposited by electroless plating of the metal resulting in a barrier layer only at those positions where the metal is opened enclosing the residual metal together with the residues of the first barrier layer. The encapsulation layer can be TEOS or SiN, it can be used to prevent the permeation of substances through the permeable layer and/or to enable the integration of further devices as e.g. sensors. The final device consists of a configuration of microtubes essentially arranged in a plane essentially parallel to the substrate where most of the microtubes on two sides are separated from one or two microtubes by only one layer of material (the first barrier layer). The thickness of this one layer of material depends on the material itself and the selectivity of the etching procedure with respect to the second disposable layer (metal layer) and the first barrier layer as described above. A thickness of this one layer of around 10 nm can be realized with this method. In general the range of the thickness of this layer is between 5 nm and 100 nm.

In one further embodiment the method for manufacturing a micro device comprises the steps of:
depositing a first disposable layer on a substrate;
depositing a permeable dielectric layer on top of the first disposable layer;
structuring the first disposable layer and the permeable dielectric layer;
depositing a first barrier layer on top of the structured stack built by the first disposable layer and the permeable dielectric layer;
depositing a second disposable layer on top of the first barrier layer;
removing the second disposable layer and the first barrier layer up to the structured permeable dielectric layer;
removing the first disposable layer through the permeable dielectric layer;
depositing a second barrier layer on top of the residual structures of the second disposable layer and the permeable dielectric layer;
depositing an encapsulation layer on top of the second barrier layer;
opening the second disposable layer through the encapsulation layer and the second barrier layer building at least two vias to the second disposable layer;
depositing a third barrier layer;
removing the third barrier layer on top of the second disposable layer building at least two openings and
selectively removing the second disposable layer.

The first disposable layer can be a thermal degradable polymer (TDP) that can be removed by means of heat through the permeable layer as described e.g. in EP 1577939 A2 (see e.g. FIG. 1-FIG. 12 and the belonging description). The second disposable layer can be metal that can be removed by means of an etching solution etching the metal very fast but etching the barrier layer very slow. The metal layer and the barrier layer on top of the TDP can be removed by planarization techniques as described e.g. in WO 2004/023550 A1 (see e.g. FIG. 1 and FIG. 2 and the belonging description). The second barrier layer is used to enclose the residues of the metal. It can be deposited by electroless plating of the metal resulting in a barrier layer only at those positions where the metal is opened enclosing the residual metal together with the residues of the first barrier layer. The encapsulation layer can be used to prevent the permeation of substances through the permeable layer and/or to enable the integration of further devices as sensors.

Alternatively a barrier layer can be deposited on top of the planarized second disposable layer by e.g. sputtering. In this case the second disposable layer has not to be conductive as if electroless plating is used. The second barrier can be used to encapsulate the permeable layer since it covers the whole planarized surface. A separate encapsulation layer is not necessary but it can be used for further integration steps as described above. The final device consists of a configuration of microtubes essentially arranged in a plane essentially parallel to the substrate where most of the microtubes on two sides are separated from one or two microtubes by only one layer of material (the first barrier layer). The thickness of this one layer of material depends on the material itself and the selectivity of the etching procedure with respect to the second disposable layer (metal layer) and the first barrier layer as described above. A thickness of this one layer of around 10 nm can be realized with this method. In general the range of the thickness of this layer is between 5 nm and 100 nm.

It's further an objective of the current invention to provide a micro device for highly efficient and compact heating or cooling. The objective is achieved by means of a micro device comprising at least one substrate, the substrate is directly or indirectly attached to at least two microtubes and a barrier layer separates the microtubes from each other. The microtubes are directly attached to the substrate if there is no intermediate layer between the substrate and the microtubes. In a cross section perpendicular to the direction where the microtube or microtubes extend, the microtube or microtubes can have a cross sectional area between 10 nm×10 nm and 10 μm×10 μm. The only one barrier layer enables thin walls between the microtubes. If the microtubes are arranged next to each other only separated by means of the barrier layer, the microtubes essentially form a layer having low thermal conductivity perpendicular to the extension of the layer with the microtubes in comparison with a layer of the same thickness without microtubes. The layer with the microtubes can correspondingly be used for thermal isolation between layers and devices below and above the layer with the microtubes. Further the layer with the microtubes can be used to compensate mechanical stress. More than one layer of microtubes can be stacked on top of each other separated by means of a spacer layer if necessary.

In one embodiment of the current invention each of the microtubes of the micro device has at least two openings. The system of two different microtubes can be flood by means of the openings with fluids. If the fluids flow through the microtubes they exchange heat. Consequently this embodiment can be used as heat exchanger for heating or cooling the fluids. The cross sectional area of the microtubes in this embodiment is preferably between 50 nm×50 nm and 500 nm×500 nm, whereby the cross section is not necessarily square. The relation between surface area and volume is of importance if the micro fluidic device is used as a heat exchanger. Cooling or heating is most effective if the area of the barrier separating two microtubes is large in comparison to the volume of the microtubes maximizing the heat exchange between both microtubes. In order to give one simple example two microtubes share one barrier layer at the entire length L of their extension. The height of the barrier layer and both microtubes is given by H. Consequently the area A1 of the barrier separating two microtubes is given by the product L*H. The width of both microtubes perpendicular to their extension is given by W resulting in a volume V1 of both microtubes given by W*L*H. The relation of A1/V1 is given by 1/W1 that means the smaller the width of the microtubes the bigger is surface A1 where heat is exchanged in comparison to the volume V1 of the microtubes. Depending on the structuring methods there are some limitations with respect to the resolution that can be achieved in order to define the width of the microtubes on the one side, and on the other side the viscosity of the liquids flowing through the microtubes may define lower limits of the cross-sectional area of the microtubes as well in order to get a reasonable cooling or heating.

A first configuration for a heat exchanger is a combination of two microtubes being arranged in a way that they wind in a spiral like manner adjacent to each other in a plane essentially parallel to the substrate. In this configuration the microtubes would be near to each other at two sides of the microtubes nearly along the whole length of the microtubes being favorable for an efficient heat exchange between fluids with different temperature. In a second configuration the microtubes with the fluids with different temperature are arranged in an alternating manner in a plane essentially parallel to the substrate. One microtube with a fluid with a temperature T1 does have two adjacent microtubes with a fluid with a temperature T2 again optimizing the heat exchange between the fluids (this is not valid for the microtubes at the border of the heat exchanger). The one barrier layer between the microtubes enables to decrease the distance between the microtubes improving the heat transfer. The thinner the barrier layer is the faster the heat can be exchanged. In addition high thermal conductivity of the barrier layer is favorable for heat exchangers. Further heating elements as conductors with high resistance can be placed next to parts of one of the microtubes in order to heat one fluid. In an analogue way parts of one microtube can be cooled by means of a Peltier-Element. The heating element and the Peltier-Element can be integrated in the device.

In a further embodiment of the micro device the microtubes are covered by at least one encapsulation layer of material or materials and the at least two openings of each of the microtubes are accessible via the encapsulation layer. The additional layer or layers can be used to integrate further functional devices as e.g. lab on the chip configurations those have to be thermally isolated from other devices or those needing a heat exchanger for e.g. analytical purposes or synthesizing. Further the encapsulation layer can be used to integrate sensors for measuring the temperature of the fluids and/or the flow of the fluids. Valves, heaters and pumps based on MEMS technology can be integrated for controlling the micro device.

In a further embodiment of the invention the micro device comprises at least one first isolation layer and at least one second isolation layer, each of the isolation layers has a low thermal conductivity, and the microtubes are sandwiched between the first and the second isolation layer. The isolation layers may comprise a material of low thermal conductivity or further microtubes building a layer of low thermal conductivity. Further openings to the microtubes embedded between the isolation layers can be provided in order to let liquids flow through the embedded microtubes. The thermal isolation of the embedded microtubes enables a more efficient heat exchanger by limiting the heat exchange with the environment. In addition the heat exchange with additional devices (e.g. sensors) thermally isolated form the heat exchanger by means of the isolation layers is reduced limiting the influence of the heat exchanger with respect to the functionality of the devices (e.g. accuracy of measurement).

FIG. 1 shows a principal sketch of one embodiment of the current invention

FIG. 2a-2f show a first process flow to manufacture a device according to the current invention

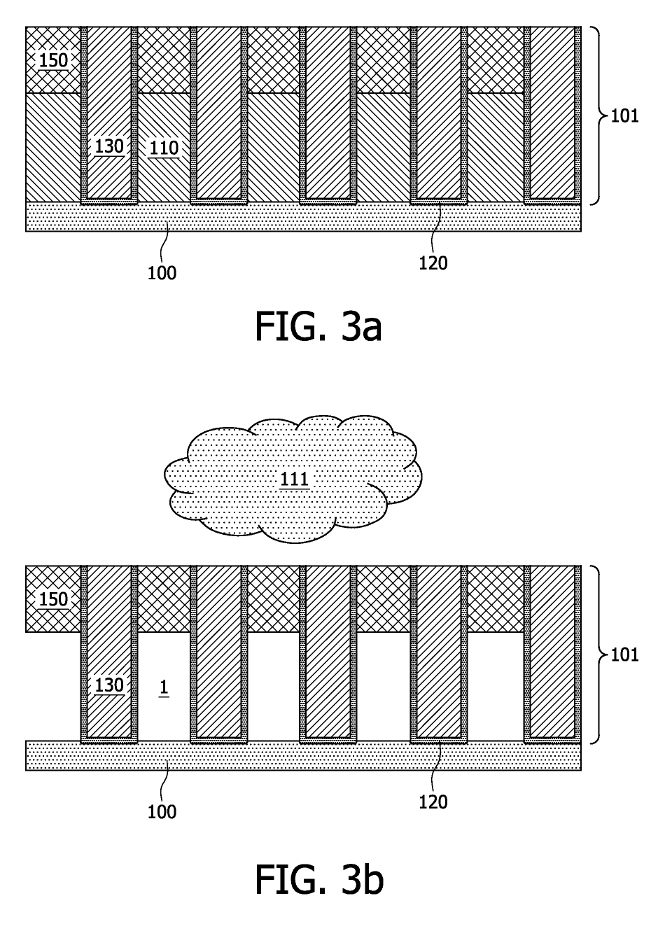

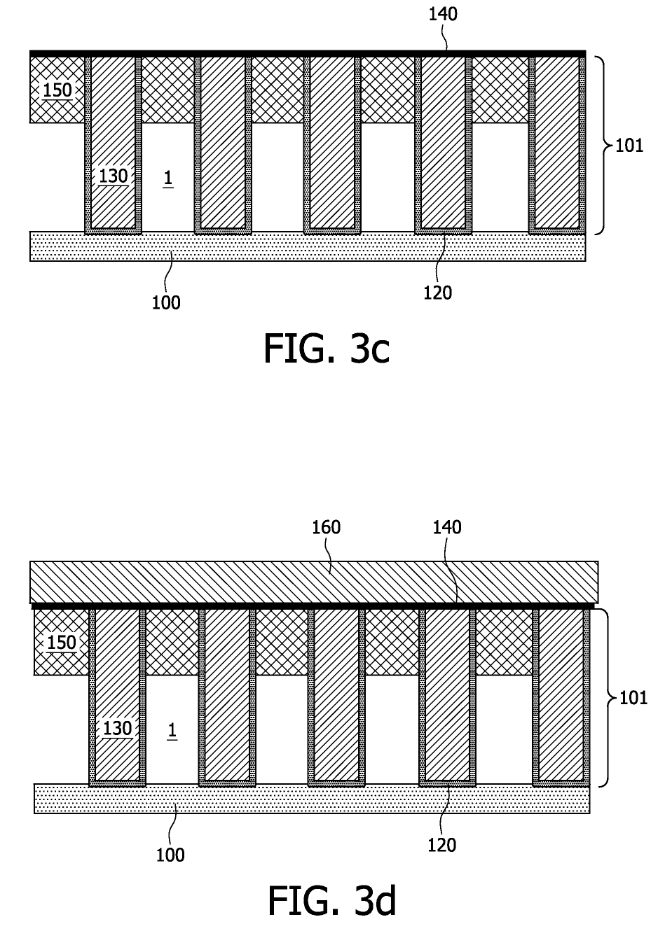

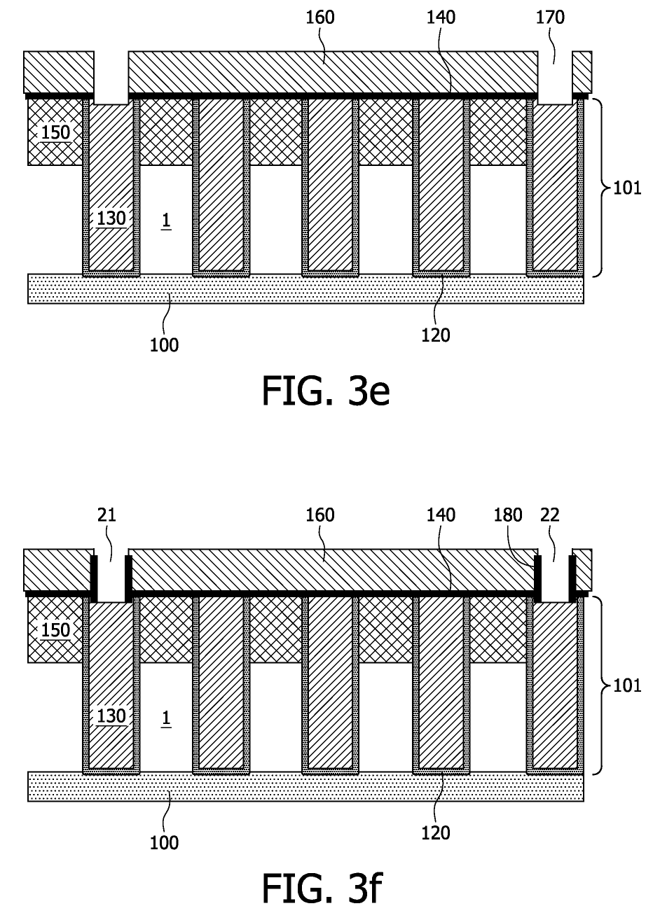

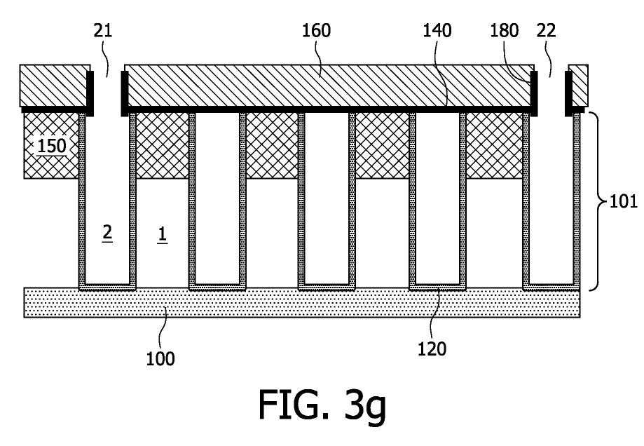

FIG. 3a-3g show a second process flow to manufacture a device according to the current invention

FIG. 1 shows a cross section parallel to the substrate of a first embodiment of the current invention. Two microtubes 1 and 2 twine next to each other in a spiral like pattern from an outer region to an inner region. The second microtube 2 shares two sides of its surface with the first microtube 1 along the whole length of the second microtube 2. The first microtube 1 is accessible by means of the openings 11 and 12 and the second microtube 2 is accessible by means of the openings 21 and 22. If a fluid with a temperature T1 flows in microtube 1 first passing opening 12 it transfers heat with a second fluid with a temperature T2 flowing in microtube 2 after the second fluid first passes opening 21. If the first fluid is cooler than the second fluid (T1<T2), the first fluid heats up during passing the first microtube 1 and is hotter after leaving the first microtube 1 at opening 11. The second fluid on the other side is cooler after leaving the second microtube 2 at opening 22. The micro device can either be used for cooling or heating.

FIG. 2a-2f show a first process flow to manufacture a device according to the current invention. FIG. 2a shows a principal sketch of a cross sectional view of a structure metal 130 embedded in two barrier layers 120 and 140 in a thermal degradable polymer (TDP). On a substrate 100 being silicon, glass or ceramics a first disposable TDP layer 110 has been deposited that decomposes at temperatures between 300° C. and 500° C. The TDP layer 110 has been structured and partly removed up to the substrate 100 in a way that channels essentially with an rectangular cross-sectional area perpendicular to the extension of the channels are formed in the TDP layer 110. A first barrier layer 120 of TaN has been deposited on top of the residues of the TDP layer 110 also covering the sides and the bottom of the channels in the TDP layer 110. In the following step copper has been deposited on top of the TaN layer 120 filling the space between the residues of the TDP layer 110 building the second disposable layer 130. After planarization of the copper and parts of the TaN layer 120 the residues of the TDP layer 110 and the residues of the copper 130 are freely accessible. The residues of the copper 130 are selectively capped using electroless self aligned barriers (e.g. CoWP, CoWB or NiMoP) building the second barrier layer 140. This process step is followed by CVD deposition of Black Diamond-1 of AMAT building a permeable dielectric layer 150.

FIG. 2b shows the formation of the first microtube 1 by means of the decomposition of the residues of the TDP layer 110 permeating as vapor 111 through the permeable dielectric layer 150. In FIG. 2c the deposition of the encapsulation layer 160 a further CVD layer (e.g. TEOS) on top of the permeable dielectric layer 150 is shown. FIG. 2d shows the patterning of the CVD layer 160 and the permeable dielectric layer 150. As well a damascene patterning scheme (layer by layer etching) as a single-via patterning can be used. In addition the second barrier layer 140 is removed on top of the residues of copper 130 now being accessible at two spots by means of the vias 170. In FIG. 2e the encapsulation layer the sides of the vias 170 and the copper accessible through the vias 170 are covered with PVD TaN 180 building the third barrier layer 180. The PVD TaN 180 is removed from the encapsulation layer 160 and the copper 130 by means of re-sputtering (using an Ar-preclean) leaving a vertical barrier layer 180 in the vias 170 covering and protecting the permeable layer 150. In the final step depicted in FIG. 2f the residues of copper 130 are removed by means of sulfuric acid. The second microtube 2 is built accessible by means of the openings 21 and 22 (openings 11 and 12 are not visible in this cross sectional view).

FIG. 3a-3g show a second process flow to manufacture a device according to the current invention. FIG. 3a shows a principal sketch of a cross sectional view of a structure metal 130 embedded in two barrier layers 120 and 140 in a thermal degradable polymer (TDP) and a permeable dielectric layer. On a substrate 100 being silicon, glass or ceramics a first disposable TDP layer 110 has been deposited that decomposes at temperatures between 300° C. and 500° C. This process step is followed by CVD deposition of Black Diamond-1 of AMAT building a permeable dielectric layer 150. The TDP layer 110 and the permeable dielectric layer 150 have been structured and partly removed up to the substrate 100 in a way that channels essentially with an rectangular cross-sectional area perpendicular to the extension of the channels are formed in the TDP layer 110. A first barrier layer 120 of TaN has been deposited on top of the permeable dielectric layer 150 and the residues of the TDP layer 110 also covering the sides and the bottom of the channels in the TDP layer 110 and the permeable dielectric layer 150. In the following step copper has been deposited on top of the TaN layer 120 filling the channels in the structured permeable dielectric layer 150 and the residues of the TDP layer 110 building the second disposable layer 130. After planarization of the copper 130 and parts of the TaN layer 120 the structured permeable dielectric layer 150 and the residues of the copper 130 are freely accessible from the top side. FIG. 3b shows the formation of the first microtube 1 by means of the decomposition of the residues of the TDP layer 110 permeating as vapor 111 through the permeable dielectric layer 150. In FIG. 3c the deposition of a second barrier layer 140 (TaN) on top of the permeable dielectric layer 150 is shown followed by the deposition of the encapsulation layer 160 (e.g. TEOS) by means of CVD shown in FIG. 3d. FIG. 3e shows the patterning of the encapsulation layer 160 and the second barrier layer 140. The residues of copper 130 are now accessible at two spots by means of the vias 170. In FIG. 3f the encapsulation layer the sides of the vias 170 and the copper accessible through the vias 170 are covered with PVD TaN 180 building the third barrier layer 180. The PVD TaN 180 is removed from the encapsulation layer 160 and the copper 130 by means of re-sputtering (using an Ar-preclean) leaving a vertical barrier layer 180 in the vias 170 covering and protecting the permeable layer 150. In the final step depicted in FIG. 3g the residues of copper 130 are removed by means of sulfuric acid. The second microtube 2 is built accessible by means of the openings 21 and 22 (openings 11 and 12 are not visible in this cross sectional view).

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, first, second and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

1. A method for manufacturing a micro device comprising the steps of:
providing a substrate (100);
providing and structuring a first disposable layer (110);
providing at least one barrier layer (120, 140);
providing a second disposable layer (130);
building a first microtube (1) by removing the first disposable layer (110) and
building a second microtube (2) by selectively removing the second disposable layer (130).

2. A method for manufacturing a micro device according to claim 1 comprising the additional steps of:
providing a permeable layer (150);
removing the first disposable layer (110) via the permeable layer (150) and
providing and patterning an encapsulation layer (160);
selectively removing the second disposable layer (130) embedded in the at least one barrier layer (120, 140).

3. A method for manufacturing a micro device according to claim 2 comprising the steps of:
depositing a first disposable layer (110) on a substrate (100);
structuring the first disposable layer (110);
depositing a first barrier layer (120) on top of the structured first disposable layer (110);
depositing a second disposable layer (130) on top of the first barrier layer;
removing the second disposable layer (130) and the first barrier layer (120) up to the structured first disposable layer (110);
plating the residues of the second disposable layer (130) with a second barrier layer (140);
depositing a permeable dielectric layer (150) on top of the second barrier layer (140) and the structured first disposable layer (110);
removing the first disposable layer (110) through the permeable dielectric layer (150);
depositing an encapsulation layer (160) on top of the permeable dielectric layer (150);
opening the second disposable layer (130) through the encapsulation layer (160), the permeable dielectric layer (150) and the second barrier layer (140) building at least two vias (170) to the second disposable layer (130);
depositing a third barrier layer (180);
removing the third barrier layer (180) on top of the second disposable layer (130) building at least two opening (21, 22) and
selectively removing the second disposable layer (130).

4. A method for manufacturing a micro device according to claim 2 comprising the steps of:
depositing a first disposable layer (110) on a substrate (100);
depositing a permeable dielectric layer (150) on top of the first disposable layer (110);
structuring the first disposable layer (110) and the permeable dielectric layer (150);
depositing a first barrier layer (120) on top of the structured stack built by the first disposable layer (110) and the permeable dielectric layer (150);
depositing a second disposable layer (130) on top of the first barrier layer;
removing the second disposable layer (130) and the first barrier layer (120) up to the structured permeable dielectric layer (150);
removing the first disposable layer (110) through the permeable dielectric layer (150);
depositing a second barrier layer (140) on top of the residual structures of the second disposable layer (130) and the permeable dielectric layer (150);
depositing an encapsulation layer (160) on top of the second barrier layer (140);
opening the second disposable layer (130) through the encapsulation layer (160) and the second barrier layer (140) building at least two vias (170) to the second disposable layer (130);
depositing a third barrier layer (180);
removing the third barrier layer (180) on top of the second disposable layer (130) building at least two opening (21, 22) and
selectively removing the second disposable layer (130).

5. A micro device comprising at least one substrate (100), the substrate (100) is directly or indirectly attached to at least two microtubes (1, 2) and a barrier layer (120, 140) separates the microtubes (1, 2) from each other.

6. A micro device according to claim 5, whereby each of the microtubes (1, 2) has at least two openings (11, 12, 21, 22).

7. A micro device according to claim 5, whereby the microtubes (1, 2) are covered by at least one encapsulation layer (160) of material or materials and the at least two openings (11, 12, 21, 22) of each of the microtubes (1, 2) are accessible via the encapsulation layer (160).

8. A micro device according to claim 1 comprising at least one first isolation layer and at least one second isolation layer, each of the isolation layers has a low thermal conductivity, and the microtubes (1, 2) are sandwiched between the first and the second isolation layer.
